(19) United States
(12) Patent Application Publication
(10) Pub. No.: US 2011/0122111 A1
(43) Pub. Date: May 26, 2011

(54) DISPLAY DEVICE

(76) Inventors: Christopher Brown, Oxford (GB); Kohei Tanaka, Osaka (JP); Hiromi Katoh, Osaka (JP)

(21) Appl. No.: 12/995,808

(22) PCT Filed: Mar. 6, 2009
(86) PCT No.: PCT/JP2009/060164

§ 371 Date: Dec. 2, 2010

(30) Foreign Application Priority Data
Jun. 3, 2008 (JP) 2008-146071

(51) Int. Cl. G09G 3/36; G09G 5/00

(52) U.S. Cl. 345/207; 345/87

(57) ABSTRACT

A display device includes a photosensor on an active matrix substrate. The photosensor includes a photodetection element (D1) that receives incident light; reset signal wiring (RST) that supplies a reset signal to the photosensor; readout signal wiring (RWS) that supplies a readout signal to the photosensor; and a sensor switching element (M2) that, in accordance with the readout signal, reads out photocurrent that has been output from the photodetection element (D1) from when the reset signal is supplied until when the readout signal is supplied. The sensor switching element (M2) is a four-terminal amplifier having two control electrodes, such as a double gate TFT or a floating gate TFT.

### TECHNICAL FIELD

The present invention relates to a display device with a photosensor having a photodetection element.

### BACKGROUND ART

Conventionally, there has been proposed a display device with an image pick-up function that, due to including a photodetection element such as a photodiode inside a pixel, can pick up an image of an object that has come close to the display. Such display devices with an image pick-up function are anticipated to be used as bidirectional communication display devices and display devices with a touch panel function.

With a conventional display device with an image pick-up function, when using a semiconductor process to form known constituent elements such as signal lines, scan lines, TFTs (Thin Film Transistor), and pixel electrodes on an active matrix substrate, a photodiode is simultaneously formed in a pixel (see PTL 1 and NPL 1 listed below).

FIG. 23 shows an example of a conventional photosensor (PTL 2 and 3) formed on an active matrix substrate. The conventional photosensor shown in FIG. 23 is configured by a photodiode PD, a capacitor C_{INT}, and a transistor M2. The anode of the photodiode PD is connected to wiring RST, which is for supplying a reset signal. The cathode of the photodiode PD is connected to one electrode of the capacitor C_{INT} and the gate of the transistor M2. The drain of the transistor M2 is connected to wiring VDD, and the source is connected to wiring OUT. In FIG. 23, the potential of the connection point between the cathode of the photodiode PD, the one electrode of the capacitor C_{INT}, and the gate of the transistor M2 is noted as V_{INT}. The other electrode of the capacitor C_{INT} is connected to wiring RWS, which is for supplying a readout signal.

In this configuration, the reset signal and the readout signal are respectively supplied to the wiring RST and the wiring RWS at predetermined times, thus enabling obtaining sensor output that is in accordance with the amount of light received by the photodiode. A description is now given of operations of the conventional photosensor shown in FIG. 23, with reference to FIG. 24. Note that the reset signal at low level (e.g., −4 V) is shown as V_{RSTL}, the reset signal at high level (e.g., 0 V) is shown as V_{RSTH}, the readout signal at low level (e.g., 0 V) is shown as V_{RWSL}, and the readout signal at high level (e.g., 8 V) is shown as V_{RWSH}.

First, when the high level reset signal V_{RSTH} is supplied to the wiring RST (time t=RST in FIG. 24), the photodiode PD becomes forward biased, and the potential V_{INT} of the gate of the transistor M2 is expressed by Expression (1) below.

V_{INT}=V_{RSTH}−V_{F} (1)

In Expression (1), V_{F} is the forward voltage of the photodiode PD, and ΔV_{RST} is the pulse height of the reset signal (V_{RSTH}−V_{RSTL}), and since V_{INT} is lower than the threshold voltage of the transistor M2 at this time, the transistor M2 is in a non-conducting state in the reset period.

Next, the reset signal returns to the low level V_{RSTL}, and thus the photocurrent integration period (period T_{INT} shown in FIG. 24) begins. In the integration period, a photocurrent that is proportionate to the amount of incident light received by the photodiode PD flows out of the capacitor C_{INT}, and thus the capacitor C_{INT} discharges. Accordingly, the potential V_{INT} of the gate of the transistor M2 when the integration period ends is expressed by Expression (2) below.

V_{INT}=V_{RSTH}−V_{F}−ΔV_{RST}·C_{PD}/C_{T}−I_{PHOTO}·T_{INT}/C_{T} (2)

In Expression (2), I_{PHOTO} is the photocurrent of the photodiode PD, and T_{INT} is the length of the integration period. In the integration period as well, V_{INT} is lower than the threshold voltage of the transistor M2, and therefore the transistor M2 is in the non-conducting state. C_{PD} is the capacitance of the photodiode PD. C_{T} is the sum of the capacitance of the capacitor C_{INT}, the capacitance C_{PD} of the photodiode PD, and a capacitance C_{TFT} of the transistor M2.

When the integration period ends, the readout signal RWS rises at a time t=RWS shown in FIG. 24, and thus the readout period begins. Here, the injection of charge into the capacitor C_{INT} occurs. As a result, the potential V_{INT} of the gate of the transistor M2 is expressed by Expression (3) below.

V_{INT}=V_{RSTH}−V_{F}−I_{PHOTO}·T_{INT}/C_{T}+ΔV_{RWS}·C_{INT}/C_{T} (3)

ΔV_{RWS} is the pulse height of the readout signal (V_{RWSH}−V_{RWSL}). Accordingly, since the potential V_{INT} of the gate of the transistor M2 becomes higher than the threshold voltage, the transistor M2 enters the conducting state and functions as a source follower amplifier along with a bias transistor (not shown in FIG. 24) provided at the end of the wiring OUT in each column. In other words, the output signal voltage from the transistor M2 is proportionate to the integral value of the photocurrent of the photodiode PD in the integration period.

Note that in FIG. 24, the broken line waveform indicates change in the potential V_{INT} in the case where a small amount of light is incident on the photodiode PD, and the solid line waveform indicates change in the potential V_{INT} in the case where external light has been incident on the photodiode PD. In FIG. 24, ΔV is a potential difference proportionate to the amount of light that has been incident on the photodiode PD.

### CITATION LIST

### Patent Literature

PTL 1: JP 2006.3857A
PTL 2: WO 2007/145346
PTL 3: WO 2007/145347

### Non Patent Literature

NPL 1: “A Touch Panel Function Integrated LCD Including LTPS A/D Converter”, T. Nakamura et al., SID 05 DIGEST, pp. 1,054-1,055, 2005

### DISCLOSURE OF INVENTION

### Problem to be Solved by the Invention

The conventional photosensor described above has a capacitor for accumulating photocurrent. However, when forming a photosensor on an active matrix substrate, it is preferable for the photosensor to be as small as possible, and for the number of parts configuring the photosensor to be as few as possible. For example, when forming a photosensor in a pixel such as described above, it is preferable for the area occupied by the parts configuring the photosensor to be small since the aperture ratio increases. Also, even if a photosensor is disposed outside the pixel region, it is preferable for the photosensor to be small for reasons such as the fact that a narrower frame region is preferable.

In light of the above issues, an object of the present invention is to reduce the size of a photosensor in a display device with a photosensor.

### Means for Solving Problem

In order to address the above-described issues, a display device according to the present invention is a display device including a photosensor on an active matrix substrate, the photosensor including: a photodetection element that receives incident light; reset signal wiring that supplies a reset signal to the photosensor; readout signal wiring that supplies a readout signal to the photosensor; and a sensor switching element that, in accordance with the readout signal, reads out photocurrent that has been output from the photodetection element from when the reset signal is supplied until when the readout signal is supplied, wherein the sensor switching element is a four-terminal amplifier having two control electrodes.

### Effects of the Invention

According to the present invention, it is possible to reduce the size of a photosensor in a display device with a photosensor.

### BRIEF DESCRIPTION OF DRAWINGS

FIG. 1 is a block diagram showing a schematic configuration of a display device according to an embodiment of the present invention.

FIG. 2 is an equivalent circuit diagram showing a configuration of a pixel in a display device according to Embodiment 1 of the present invention.

FIG. 3A is a plan view of a photosensor according to Embodiment 1. FIG. 3B is a cross-sectional view showing a cross section taken along A-B in FIG. 3A.

FIG. 4A is a characteristics diagram showing a relationship between potential V_{TG} of a top gate, drain current ID, and potential V_{BG} (units of V) of a bottom gate in a transistor M2. FIG. 4B is a characteristics diagram showing a relationship between drain-source potential difference V_{DS}, drain current ID, and potential. V_{BG} of the bottom gate in the transistor M2.

FIG. 5 is a timing chart showing a reset signal waveform and a readout signal waveform.

FIG. 6 is a diagram for illustrating a relationship between potential V_{INT} of a connection point INT and output signal voltage V_{SOUT}.

FIG. 7 is a timing chart showing sensor drive timing in the display device according to an embodiment of the present invention.

FIG. 8 is a circuit diagram showing an internal configuration of a sensor pixel readout circuit.

FIG. 9 is a waveform diagram showing a relationship between a readout signal, sensor output, and output of the sensor pixel readout circuit.

FIG. 10 is a circuit diagram showing an exemplary configuration of a sensor column amplifier.

FIG. 11 is an equivalent circuit diagram of a photosensor according to Embodiment 2.

FIG. 12A is a plan view of a photosensor according to Embodiment 2.

FIG. 12B is a cross-sectional diagram showing a cross section taken along A-B in FIG. 12A.

FIG. 13 is an equivalent circuit diagram of a photosensor circuit and a reference circuit included in a display device according to Embodiment 2.

FIG. 14 is an equivalent circuit diagram of a photosensor circuit and a reference circuit according to a variation of the configuration shown in FIG. 13.

FIG. 15 is an equivalent circuit diagram of a photosensor circuit and a reference circuit included in a display device according to Embodiment 3.

FIG. 16 is a waveform diagram showing a relationship between input signals (RST and RWS) and V_{INT} in a photosensor according to Embodiment 3.

FIG. 17 is an equivalent circuit diagram of a photosensor circuit and a reference circuit included in a display device according to a variation of Embodiment 3.

FIG. 18 is a waveform diagram showing a relationship between V_{INT} and various types of signals applied to a photosensor according to the variation of Embodiment 3.

FIG. 19 is a waveform diagram showing, as a comparative example, change in V_{INT} in the case where the drop in the potential of the reset signal RST was not steep in the configuration shown in FIG. 15.

FIG. 20 is an equivalent circuit diagram showing a configuration of a pixel included in a display device according to Embodiment 4.

FIG. 21A is a characteristics diagram showing a relationship between potential V_{CG1} of a control gate CG1, drain current ID, and potential V_{CG2} of a control gate CG2 in a floating gate TFT M6. FIG. 21B is a characteristics diagram showing a relationship between drain-source potential difference V_{DS}, drain current ID, and potential V_{CG2} of the control gate CG2 in the floating gate TFT MG.

FIG. 22A is a plan view showing a configuration of the floating gate TFT M6. FIG. 22B is a cross-sectional diagram showing a cross section taken along arrows A-A in FIG. 22A. FIG. 22C is a cross-sectional diagram showing a cross section taken along arrows B-B in FIG. 22A.

FIG. 23 is an equivalent circuit diagram showing an exemplary configuration of a conventional photosensor.

FIG. 24 is a waveform diagram showing V_{INT} in the case where the reset signal RST and the readout signal RWS have been applied to the conventional photosensor.

### DESCRIPTION OF THE INVENTION

A display device according to an embodiment of the present invention is a display device including a photosensor on an active matrix substrate, the photosensor including: a photodetection element that receives incident light; reset signal wiring that supplies a reset signal to the photosensor; readout signal wiring that supplies a readout signal to the photosensor; and a sensor switching element that, in accordance with the readout signal, reads out photocurrent that has been output from the photodetection element from when the reset signal is supplied until when the readout signal is supplied. Note that the sensor switching element is a four-terminal amplifier having two control electrodes.

According to this configuration, either of the control electrodes of the sensor switching element functions as a capacitance that accumulates photocurrent, thus eliminating the need to separately form a capacitance as in conventional technology. It is therefore possible to reduce the size of the photosensor in the display device with a photosensor.

A double gate TFT having a top gate and a bottom gate as the control electrodes can be used as the four-terminal amplifier. In this configuration, an aspect is possible in which the top gate is connected to output of the photodetection element, and the bottom gate is connected to the readout signal wiring, and an aspect is possible in which the top gate is connected to the readout signal wiring, and the bottom gate is connected to output of the photodetection element.

Also, it is preferable that the display device including the double gate TFT further includes: a backlight, wherein the photosensor further includes a light-shielding layer between the photodetection element and the backlight, and the light-shielding layer and the bottom gate are formed from the same metal material. This enables the light-shielding layer and the bottom gate to be formed in the same process, thus improving manufacturing efficiency. Furthermore, it is preferable that the light-shielding layer and the bottom gate have the same thickness.

Alternatively, a floating gate TFT having two floating gates as the control electrodes can be used as the four-terminal amplifier.

Also, in the above-described display device, it is preferable that the photodetection element includes a photoreception element that receives light, and a reference element that is shielded from light by the light-shielding layer and detects dark current, and the display device further includes a correction circuit that corrects output of the photoreception element with use of output from the reference element. This is because it is possible to compensate for the case where the characteristics of the photodetection element vary due to variations in environmental temperature. Note that the photoreception element and the reference element may be provided in a pixel region of the active matrix substrate, or may be provided outside the pixel region.

It is further preferable that the light-shielding layer is formed from the same material as any metal layer formed on the active matrix substrate (examples of which include, but are not limited to, an electrode of an active element, various types of wiring, or a reflective layer used in the case of a semi-transmissive liquid crystal panel or the like). This is because using the same material enables the light-shielding layer and another metal layer on the active matrix substrate to be formed in the same process, thus enabling simplifying the manufacturing process. Alternatively, it is preferable, for the same reason, that the light-shielding layer is formed from the same material as a black matrix formed on the active matrix substrate or on a common substrate.

Also, a photodiode can be used as the photodetection element. In this case, a configuration is possible in which one of the control electrodes is connected to the readout signal wiring, and the other of the control electrodes is connected to a cathode of the photodiode. Alternatively, a configuration is possible in which one of two terminals other than the control electrodes in the four-terminal amplifier is connected to constant potential wiring, and the other of the two terminals other than the control electrodes in the four-terminal amplifier is connected to sensor signal output wiring from the photosensor. As another alternative, a phototransistor can be used as the photodetection element.

The photodetection element may be provided in a pixel region of the active matrix substrate, or may be provided outside the pixel region.

Also, the above-described display device can be implemented as a liquid crystal display device further including a common substrate opposing the active matrix substrate, and liquid crystal sandwiched between the active matrix substrate and the common substrate.

Below is a description of more specific embodiments of the present invention with reference to the drawings. Note that although the following embodiments show examples of configurations in which a display device according to the present invention is implemented as a liquid crystal display device, the display device according to the present invention is not limited to a liquid crystal display device, and is applicable to an arbitrary display device that uses an active matrix substrate. It should also be noted that due to having an image pick-up function, the display device according to the present invention is envisioned to be used as, for example, a display device with a touch panel that performs input operations by detecting an object that has come close to the screen, or a bidirectional communication display device that is equipped with a display function and an image capture function.

Also, for the sake of convenience in the description, the drawings that are referred to below show simplifications of, among the constituent members of the embodiments of the present invention, only relevant members that are necessary for describing the present invention. Accordingly, the display device according to the present invention may include arbitrary constituent members that are not shown in the drawings that are referred to in this specification. Also, regarding the dimensions of the members in the drawings, the dimensions of the actual constituent members, the ratios of the dimensions of the members, and the like are not shown faithfully.

### Embodiment 1

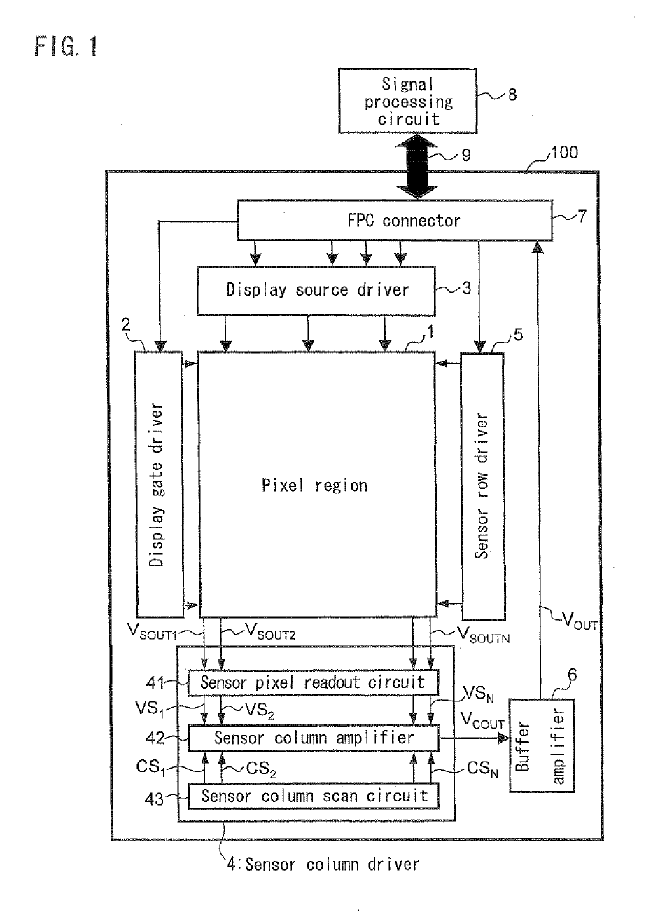

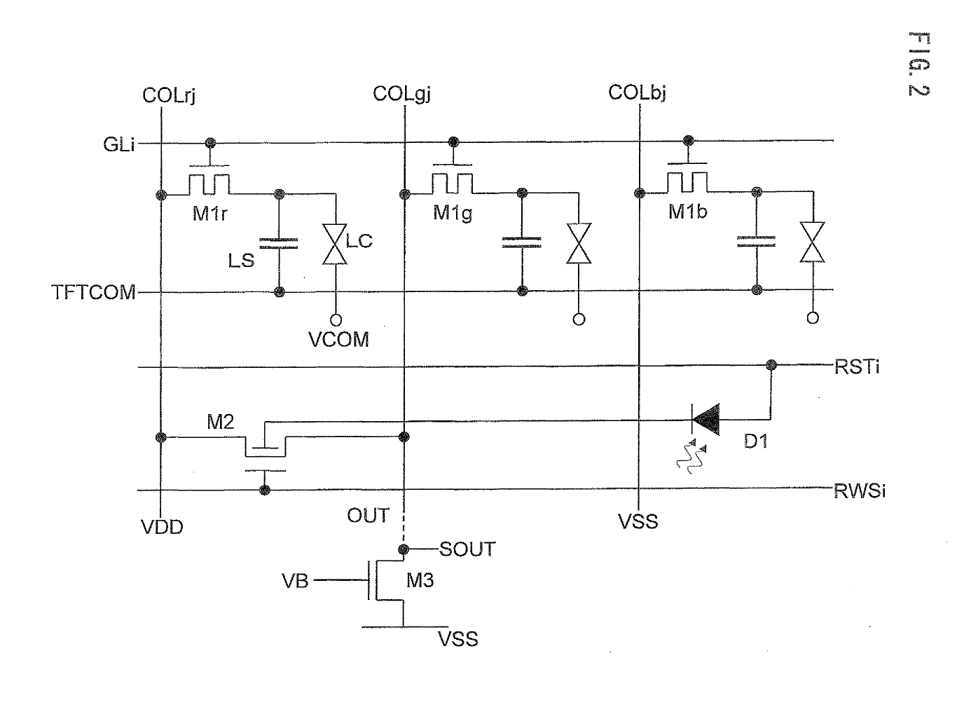

First, a configuration of an active matrix substrate included in a liquid crystal display device according to Embodiment 1 of the present invention is described with reference to FIGS. 1 and 2.

FIG. 1 is a block diagram showing a schematic configuration of an active matrix substrate 100 included in the liquid crystal display device according to an embodiment of the present invention. As shown in FIG. 1, the active matrix substrate 100 includes at least a pixel region 1, a display gate driver 2, a display source driver 3, a sensor column driver 4, a sensor row driver 5, a buffer amplifier 6, and an FPC connector 7 on a glass substrate. Also, a signal processing circuit 8 for, processing image signals picked up by a photodetection element (described later) in the pixel region 1 is connected to the active matrix substrate 100 via the FPC connector 7 and an FPC 9.

Note that the above constituent members on the active matrix substrate 100 can also be formed monolithically on the glass substrate by a semiconductor process. Alternatively, a configuration is possible in which the amplifier and various drivers among the above constituent members are mounted on the glass substrate by COG (Chip On Glass) technology or the like. As another alternative, it is possible for at least a portion of the above constituent members shown on the active matrix substrate 100 in FIG. 1 to be mounted on the FPC 9. The active matrix substrate 100 is attached to a common substrate (not shown) that has a common electrode formed on the entire face thereof, and a liquid crystal material is enclosed in the gap therebetween.

The pixel region 1 is a region in which a plurality of pixels are formed in order to display an image. In the present embodiment, a photosensor for picking up an image is provided in each pixel in the pixel region 1. FIG. 2 is an equivalent circuit diagram showing the disposition of the pixels and photosensors in the pixel region 1 of the active matrix substrate 100. In the example in FIG. 2, each pixel is formed by three colors of picture elements, namely R (red), G (green), and B (blue), and one photosensor is provided in each of the pixels configured by these three picture elements. The pixel region 1 has pixels disposed in a matrix having M rows×N columns, and photosensors that are likewise disposed in a matrix having M rows×N columns. Note that as described above, the number of picture elements is M×3N.

For this reason, as shown in FIG. 2, the pixel region 1 has, as wiring for the pixels, gate lines GL and source lines COL that are disposed in a matrix. The gate lines GL are connected to the display gate driver 2. The source lines COL are connected to the display source driver 3. Note that the gate lines GL are provided in M rows in the pixel region 1. Hereinafter, the notation GLi (i=1 to M) is used when there is a need to distinguish between individual gate lines GL in the description. Meanwhile, three of the source lines COL are provided in each pixel in order to respectively supply image data to the three picture elements in each pixel as described above. The notations COLrj, COLgj, and COLbj (j=1 to N) are used when there is a need to distinguish between individual source lines COL in the description.

Thin film transistors (TFT) M1 are provided as switching elements for the pixels at intersections between the gate lines GL and the source lines COL. Note that in FIG. 2, the thin film transistors M1 provided in the red, green, and blue picture elements are noted as M1r, M1g, and M1b respectively. In each thin film transistor M1, the gate electrode is connected to one of the gate lines GL, the source electrode is connected to one of the source lines COL, and the drain electrode is connected to a pixel electrode that is not shown. Accordingly, as shown in FIG. 2, a liquid crystal capacitance LC is formed between the drain electrode of each thin film transistor M1 and the common electrode (VCOM). Also, an auxiliary capacitance LS is formed between each drain electrode and a TFTCOM.

In FIG. 2, the picture element driven by the thin film transistor M1r, which is connected to the intersection between one gate line GLi and one source line COLrj, is provided with a red color filter so as to correspond to that picture element, and red image data is supplied from the display source driver 3 to that picture element via the source line COLrj, and thus that picture element functions as a red picture element. Also, the picture element driven by the thin film transistor Mfg, which is connected to the intersection between the gate line GLi and the source line COLgj, is provided with a green color filter so as to correspond to that picture element, and green image data is supplied from the display source driver 3 to that picture element via the source line COLgj, and thus that picture element functions as a green picture element. Furthermore, the picture element driven by the thin film transistor M1b, which is connected to the intersection between the gate line GLi and the source line COLbj, is provided with a blue color filter so as to correspond to that picture element, and blue image data is supplied from the display source driver 3 to that picture element via the source line COLbj, and thus that picture element functions as a blue picture element.

Note that in the example in FIG. 2, the photosensors are provided in the ratio of one per pixel (three picture elements) in the pixel region 1. However, the disposition ratio of the pixels and photosensors is arbitrary and not limited to merely this example. For example, one photosensor may be disposed per picture element, and a configuration is possible in which one photosensor is disposed for a plurality of pixels.

As shown in FIG. 2, each photosensor is configured by a photodiode D1 as a photodetection element, and a transistor M2. In the example in FIG. 2, the source line COLr also serves as wiring VDD, which is for supplying a constant voltage V_{DD} from the sensor column driver 4 to the photosensor. Also, a source line COLg also serves as wiring OUT for sensor output.

The transistor M2 is a TFT that has two gates (hereinafter, referred to as a “double gate TFT”). Here, the gate of the transistor M2 at the bottom layer (on the glass substrate side) is referred to as the bottom gate, and the gate at the top layer is referred to as the top gate. In the example in FIG. 2, the top gate is connected to the wiring RWS, and receives an application of the readout signal. The bottom gate is connected to the cathode of the photodiode D1. The drain of the transistor M2 is connected to wiring VDD, and the source is connected to wiring OUT. The anode of the photodiode D1 is connected to wiring RST, which is for supplying a reset signal.

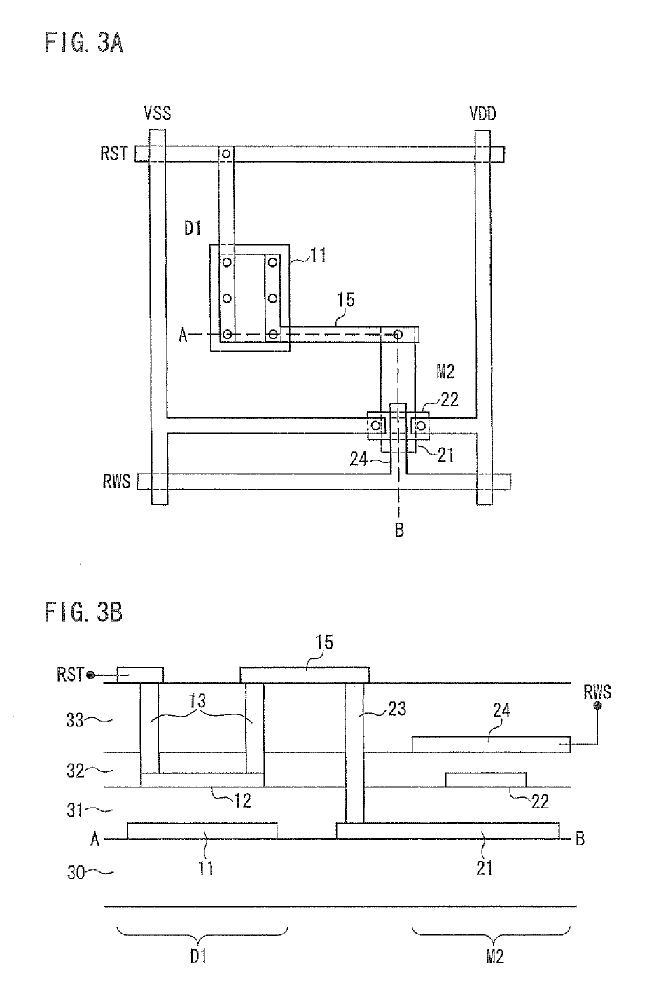

The following describes a configuration of the photosensor of the present embodiment with reference to FIGS. 3A and 3B. FIG. 3A is a plan view of the photosensor according to the present embodiment. FIG. 3B is a cross-sectional view showing a cross section taken along A-B in FIG. 3A.

As shown in FIGS. 3A and 3B, the photodiode D1 and the transistor M2 are formed by a semiconductor process on a glass substrate 30 of the active matrix substrate 100. The photodiode D1 is configured by a light-shielding layer 11, a gate insulating film 31, a semiconductor layer 12, a gate insulating film 32, and an insulating layer 33 that have been stacked in the stated order. Note that in addition to the layers shown here, a base coat layer and the like may be provided. The semiconductor layer 12 of the photodiode D1 has, for example, a PN junction or a PIN junction having a lateral structure. The anode of the semiconductor layer 12 is connected to the reset signal wiring RST via a contact 13. The transistor M2 is configured by a bottom gate 21, the gate insulating film 31, a semiconductor layer 22, the gate insulating film 32, a top gate 24, and the insulating layer 33 that have been stacked in the stated order on the glass substrate 30. The cathode of the semiconductor layer 12 of the phototransistor D1 is connected to the bottom gate 21 of the transistor M2 via the contact 13, wiring 15, and a contact 23. The top gate 24 is connected to the readout signal wiring RWS.

The light-shielding layer 11 is provided in order to prevent light from a backlight (not shown) from being incident on the semiconductor layer 12 of the photodiode D1. It is preferable that the bottom gate 21 of the transistor M2 is formed using the same material, to the same film thickness, and by the same process as the light-shielding layer 11.

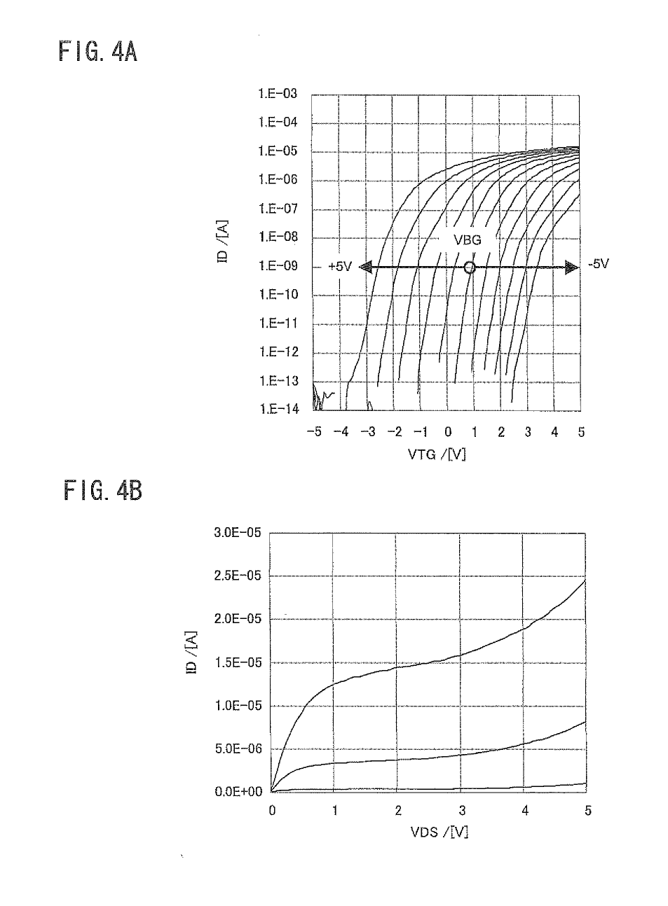

In the transistor M2 according to the configuration described above, the threshold voltage of the transistor M2 can be controlled by changing the voltage applied to the bottom gate. FIG. 4A is a characteristics diagram showing a relationship between potential V_{TG} (units of V) of the top gate, drain current ID (units of A), and potential V_{BG} (units of V) of the bottom gate in the transistor M2. Also, FIG. 4B is a characteristics diagram showing a relationship between drain sourcepotential difference V_{DS} (units of V), drain current ID (units of A), and potential V_{BG} (units of V) of the bottom gate in the transistor M2. Note that although FIG. 4A shows characteristics in the case where the potential difference between the drain and source is 0.1 V, and FIG. 4B shows characteristics in the case where the potential V_{TG} of the top gate of the transistor M2 is 5 V, these are merely examples, and the double gate TFT characteristics that are applicable to the present invention are not intended to be limited to these examples.

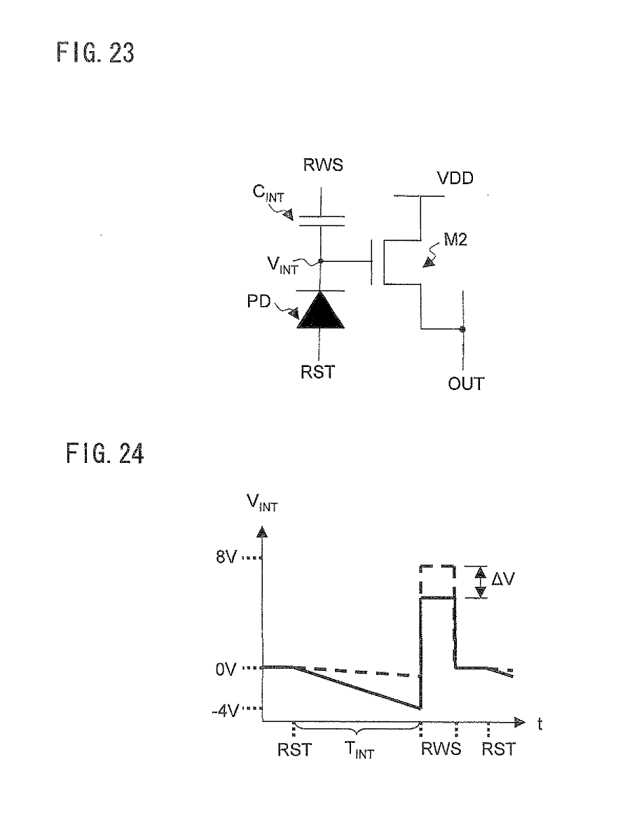

The following are advantages of using a double gate TFT as the transistor M2. Firstly, since the capacitance of the bottom gate functions as a capacitance C_{BG} that discharges photocurrent from the photodiode D1, there is no need to separately provide a capacitor C_{INT} as with the conventional photosensor shown in FIG. 23. Compared to the above-described conventional photosensor, the photosensor of the present embodiment can have fewer constituent parts since a capacitor is unnecessary, thus enabling improving the pixel aperture ratio.

Also, the top gate of the transistor M2 shields the capacitance C_{BG} of the present embodiment from the pixel electrode formed above the capacitance C_{BG}. Accordingly, the capacitance C_{BG} is not influenced by variations in the potential of the pixel electrode that accompany pixel writing, thus enabling obtaining stable sensor output. The photosensor of the present embodiment furthermore has the following advantages. Specifically, in the conventional configuration shown in FIG. 23, the degree of photosensitivity (photodiode size) directly influences the readout voltage and the readout speed, and therefore it has been necessary to take the balance between both into consideration when determining capacitance and photodiode size. However, according to the configuration of the present embodiment, the threshold of the transistor is controlled according to variations in the voltage of the bottom gate due to received light before performing readout, thus enabling setting the readout voltage and the readout speed without regard to photosensitivity (the photodiode size in the configuration in FIG. 23), and optimizing both separately.

The wiring RST and RWS are connected to the sensor row driver 5. Since the wiring RST and RSW are provided in each row, the notations RSTi and RWSi (i=1 to M) are used hereinafter when there is a need to distinguish between the wiring.

The sensor row driver 5 successively selects each group of wiring RSTi and RWSi shown in FIG. 2 at a predetermined time interval t_{row}. Accordingly, each photosensor row in the pixel region 1 from which a signal charge is to be read out is successively selected.

Note that as shown in FIG. 2, the end of the wiring OUT is connected to the drain of an insulated gate field effect transistor M3. Also, the drain of this transistor M3 is connected to output wiring S_{OUT}, and a potential V_{SOUT} of the drain of the transistor M3 is output to the sensor column driver 4 as an output signal from the photosensor. The source of the transistor M3 is connected to the wiring VSS. The gate of the transistor M3 is connected to a reference voltage power supply (not shown) via reference voltage wiring VB.

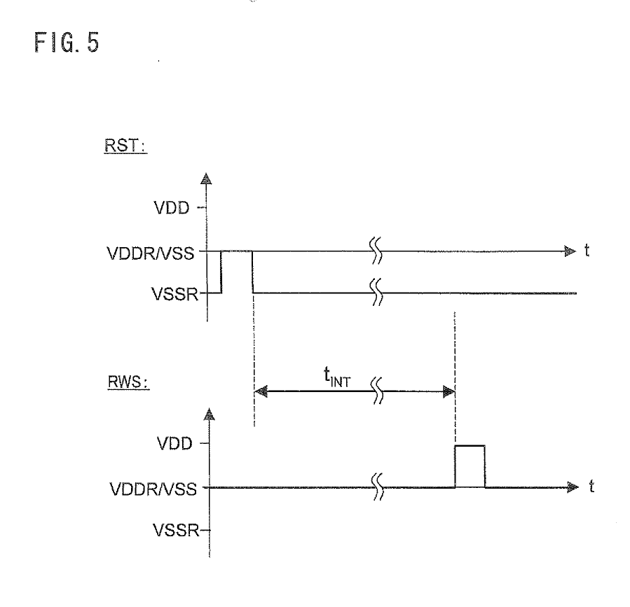

The following describes the readout of sensor output from the pixel region 1 with reference to FIG. 5. FIG. 5 is a timing chart showing the waveforms of the reset signal supplied from the wiring RST to the photosensor and the readout signal supplied from the wiring RWS to the photosensor. As shown in FIG. 5, the high level V_{RSTH} of the reset signal is 0 V, and the low level V_{RSTL}, thereof is −2 V. In this example, the high level V_{RSTH} of the reset signal is equivalent to V_{SS}. Also, the high level V_{RWSH} of the readout signal is 5 V, and the low level V_{RWSL} thereof is 0 V In this example, the high level V_{RWSH} of the readout signal is equivalent to V_{DD}, and the low level V_{RWSL} thereof is equivalent to V_{SS}.

First, when the reset signal supplied from the sensor row driver 5 to the wiring RST rises from the low level (−2 V) to the high level (0 V), the photodiode D1 becomes forward biased, and the potential V_{INT} of the connection point INT is obtained as expressed by Expression (4) below. Note that the potential V_{INT} of the connection point INT is equivalent to the potential of the bottom gate of the transistor M2.

V_{INT}=V_{RSTH}−V_{F} (4)

In Expression (4), V_{RSTH} is 0 V, which is the high level of the reset signal, V_{F} is the forward voltage of the photodiode D1, and ΔV_{RST} is the pulse height of the reset signal (V_{RSTH}−V_{RSTL}), and since the voltage of the readout signal RWS applied to the top gate is 0 V at the time of this reset, the transistor M2 is in the non-conducting state in the reset period.

Next, the reset signal returns to the low level V_{RSTL}, and thus the photocurrent integration period (t_{INT}) begins. In the integration period, a photocurrent that is proportionate to the amount of incident light received by the photodiode D1 flows out from the bottom gate, and causes the capacitance C_{BG} of the bottom gate to discharge. Accordingly, the potential V_{INT} of the connection point INT when the integration period ends is expressed by Expression (5) below.

V_{INT}=V_{RSTH}−V_{F}−ΔV_{RST}·C_{PD}/C_{T}−I_{PHOTO}·t_{INT}/C_{T} (5)

In Expression (5), I_{PHOTO} is the photocurrent of the photodiode D1, and t_{INT} is the length of the integration period. In the integration period as well, the voltage of the readout signal RWS applied to the top gate is 0 V, and therefore the transistor M2 remains in the non-conducting state. C_{PD} is the capacitance of the photodiode D1. C_{T} is the total capacitance of the connection point INT, which is the sum of the capacitance C_{BG} of the bottom gate, the capacitance C_{PD} of the photodiode D1, and a parasitic capacitance C_{PAR} of the transistor M2.

When the integration period ends, the readout signal RSW switches to high level as shown in FIG. 5, and thus the readout period begins. When the readout signal RWS rises to high level (5 V), the transistor M2 enters the conducting state. Upon entering the conducting state, the transistor M2 functions as a source follower amplifier along with the bias transistor M3 provided at the end of the wiring OUT in each column. In other words, the output signal voltage V_{SOUT} from the output wiring SOUT from the drain of the transistor M3 is a function of the amount of light received by the photodiode D1 in the integration period t_{INT}.

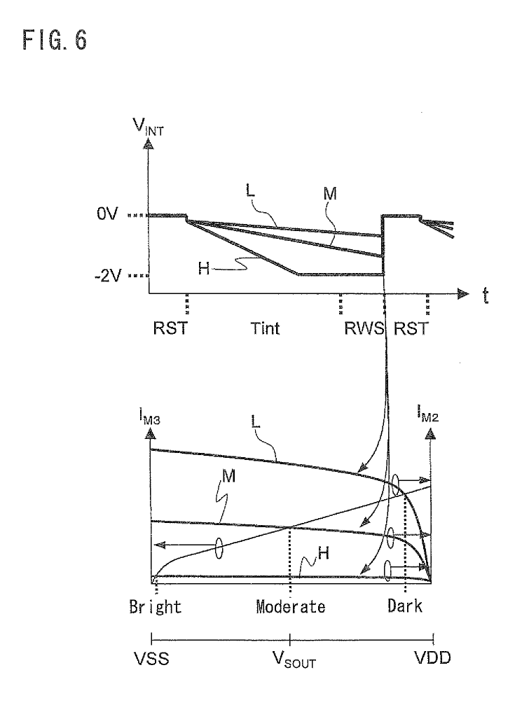

FIG. 6 is a diagram for illustrating a relationship between potential V_{INT} of the connection point INT and output signal voltage V_{SOUT}. The rate of change of the potential V_{INT} in the integration period is dependent on the surrounding brightness. If the surrounding brightness is quite high, the potential V_{INT} of the connection point INT drops steeply as shown by line H in the top graph in FIG. 6, and saturation occurs during the integration period. Also, if the surrounding brightness is moderate, the potential V_{INT} of the connection point INT drops relatively gently as shown by line M in the same graph. If the surrounding brightness is low, the potential V_{INT} of the connection point INT drops even more gently as shown by line L in the same graph. As shown in the bottom graph in FIG. 6, output signal voltage V_{SOUT} is expressed by intersections between the lines L, M, and H, which indicate output current value I_{M2} from the transistor M2, and current value I_{M3} flowing to the transistor M3. As shown in the bottom graph in FIG. 6, the values of output signal voltage V_{SOUT} are unique between VDD and VSS according to the brightness of surrounding light in the integration period. This therefore enables using the value of the output signal voltage V_{SOUT} as an indicator of surrounding brightness.

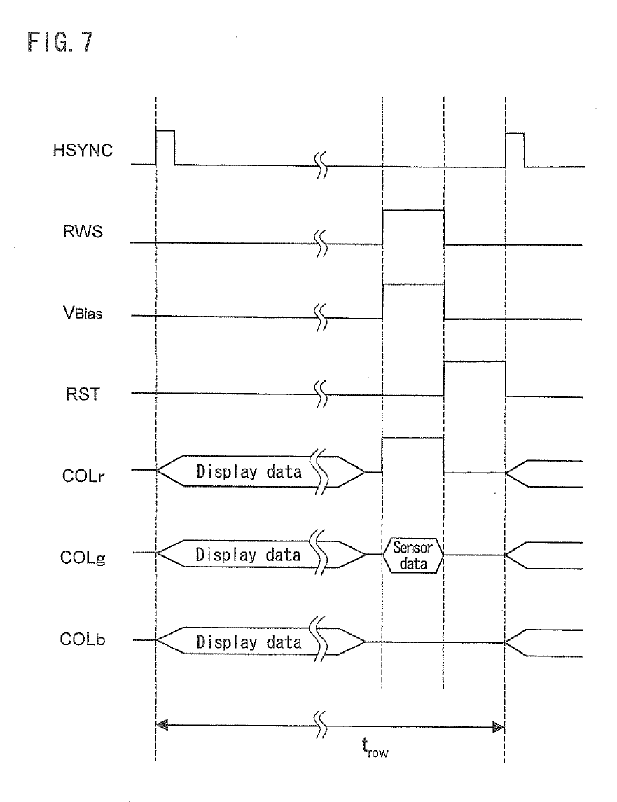

In the present embodiment, as previously described, the source lines COLr, COLg, and COLb are also used as the photosensor wiring VDD and OUT, and therefore as shown in FIG. 7, it is necessary to distinguish between times when image data signals for display are input via the source lines COLr, COLg, and COLb, and times when sensor output V_{SOUT} is read out via the source lines COT COLg, and COLb. In the example in FIG. 7, after the input of the image data signal for display in a horizontal scan period has ended, the reading out of the sensor output V_{SOUT} is performed using a horizontal blanking period or the like.

As shown in FIG. 1, the sensor column driver 4 includes a sensor pixel readout circuit 41, a sensor column amplifier 42, and a sensor column scan circuit 43. The sensor pixel readout circuit 41 is connected to the wiring SOUT (see FIG. 2) that outputs the sensor output V_{SOUT} from the pixel region 1. In FIG. 1, the sensor output that is output by wiring SOUTj (j=1 to N) is noted as V_{SOUTj}. The sensor pixel readout circuit 41 outputs peak hold voltages V_{Sj} of the sensor output V_{SOUTj} to the sensor column amplifier 42. The sensor column amplifier 42 includes an N number of column amplifiers that respectively correspond to the photosensors in the N columns in the pixel region 1, and the column amplifiers respectively amplify the peak hold voltages V_{Sj} (j=1 to N), and output the resulting peak hold voltages to the buffer amplifier 6 as V_{COUT}. The sensor column scan circuit 43 outputs column select signals CSⱼ (j=1 to N) to the sensor column amplifier 42 in order to successively connect the column amplifiers of the sensor column amplifier 42 to the output bound for the buffer amplifier 6.

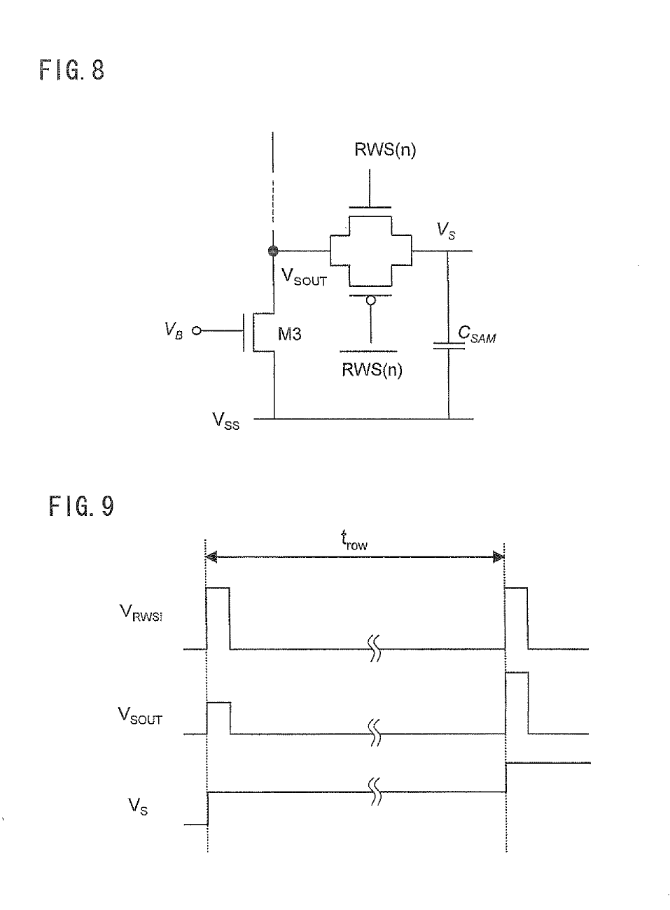

The following describes operations of the sensor column driver 4 and the buffer amplifier 6 that are performed after the sensor output V_{SOUT} has been read out from the pixel region 1, with reference to FIGS. 8 and 9. FIG. 8 is a circuit diagram showing an internal configuration of the sensor pixel readout circuit 41. FIG. 9 is a waveform diagram showing a relationship between the readout signal V_{RWS}, the sensor output V_{SOUT}, and the output V_{S} of the sensor pixel readout circuit. As previously described, when the readout signal has risen to the high level V_{RWSH}, the transistor M2 becomes conductive, and therefore a source follower amplifier is formed by the transistors M2 and M3, and the sensor output V_{SOUT} is accumulated in a sample capacitor C_{SAM} of the sensor pixel readout circuit 41. Accordingly, even after the readout signal has fallen to the low level V_{RWSL}, in the selection period of that row (t_{row}), the output voltage V_{S} from the sensor pixel readout circuit 41 to the sensor column amplifier 42 is kept at the same level as the peak value of the sensor output V_{SOUT}, as shown in FIG. 8.

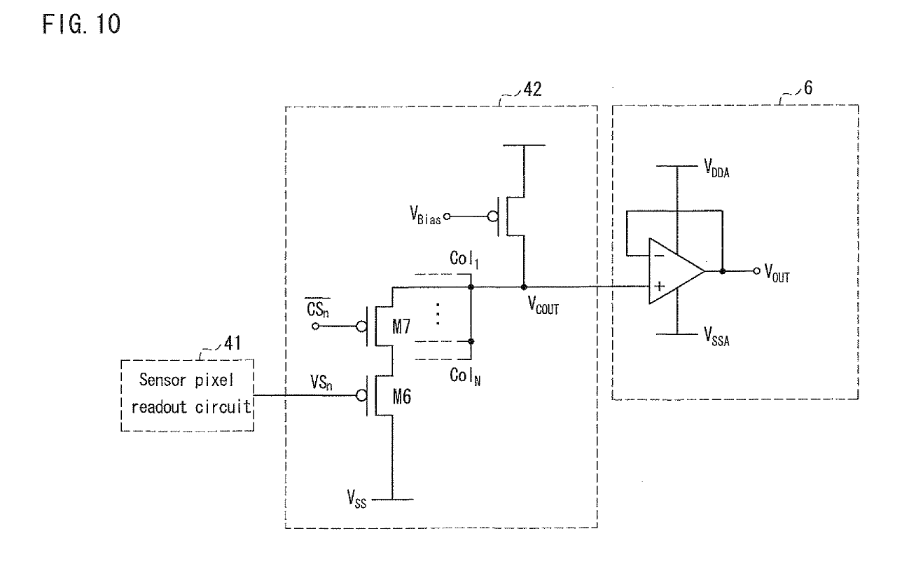

Next is a description of operations of the sensor column amplifier 42 with reference to FIG. 10. As shown in FIG. 10, the output voltages V_{Sj} (j=1 to N) of the columns are input from the sensor pixel readout circuit 41 to the N number of column amplifiers of the sensor column amplifier 42. As shown in FIG. 10, each column amplifier is configured by transistors M6 and M7. The column select signals C_{Sj} generated by the sensor column scan circuit 43 successively become ON for each of the N columns in the select period of one row (t_{row}), and therefore the transistor M6 of only one of the N number of column amplifiers in the sensor column amplifier 42 is switched on, and only one of the output voltages V_{Sj} (j=1 to N) of the columns is output as the output V_{COUT} from the sensor column amplifier 42 via that transistor M6. The buffer amplifier 6 then amplifies the V_{COUT} that has been output from the sensor column amplifier 42, and outputs the resulting amplified V_{COUT} to the signal processing circuit 8 as panel output (a photosensor signal) Vₒᵤₜ.

Note that although the sensor column scan circuit 43 may scan the photosensor columns one column at a time as described above, there is no limitation to this, and a configuration is possible in which the photosensor columns are interlace-scanned. Also, the sensor column scan circuit 43 may be formed as a multi-phase drive scan circuit that has, for example, four phases.

According to the above configuration, the display device according to the present embodiment obtains panel output V_{OUT} that is in accordance with the amount of light received by the photodiode D1 formed in each pixel in the pixel region 1. The panel output V_{OUT} is sent to the signal processing circuit 8, has A/D conversion performed thereon, and is accumulated in a memory (not shown) as panel output data. Specifically, the same number of panel output data pieces as the number of pixels (number of photosensors) in the pixel region 1 are accumulated in this memory. With use of the panel output data accumulated in the memory, the signal processing circuit 8 performs various types of signal processing such as image pickup and the detection of a touch area. Note that although the same number of panel output data pieces as the number of pixels (number of photosensors) in the pixel region 1 are accumulated in the memory of the signal processing circuit 8 in the present embodiment, due to constraints such as memory capacity, there is no need to necessarily accumulate the same number of panel output data pieces as the number of pixels.

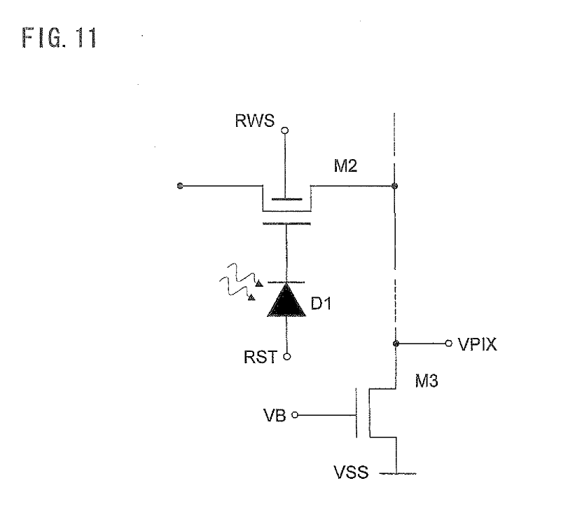

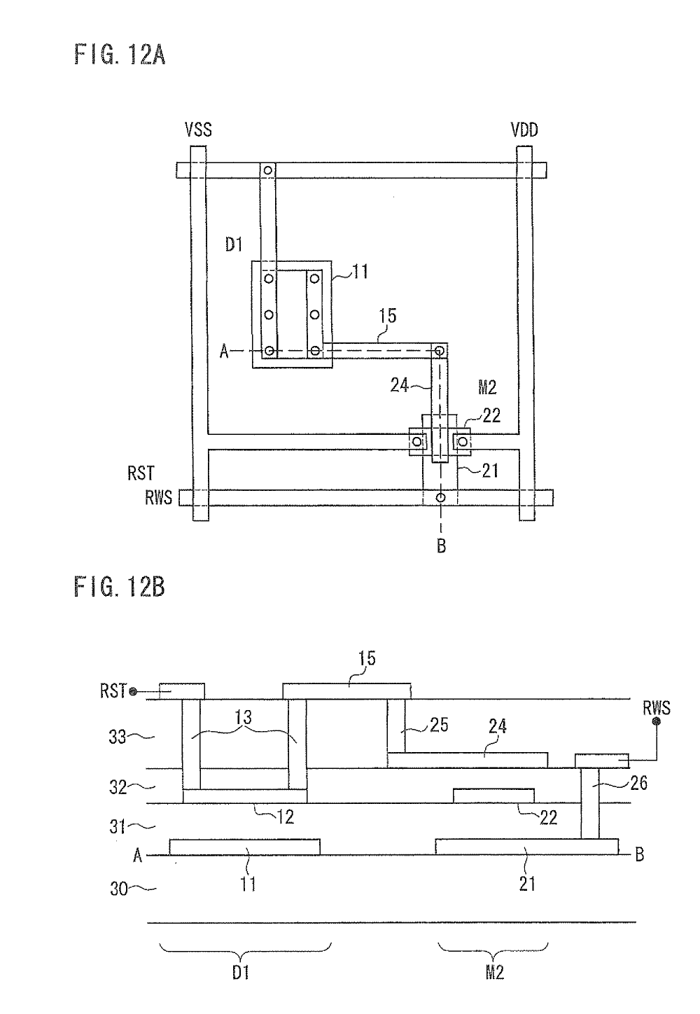

Note that in the configuration in the above-described example, the bottom gate of the transistor M2 is connected to the cathode of the photodiode D1, and the top gate is connected to the readout signal wiring RWS. However, Embodiment 1 also includes (as a variation) a configuration in which, as shown in FIG. 11, the top gate of the transistor M2 is connected to the cathode of the photodiode D1, and the bottom gate is connected to the readout signal wiring RWS. FIGS. 12A and 12B respectively show a plan view and a cross-sectional view of the transistor M2 in this case. As shown in FIGS. 12A and 12B, in this variation, the bottom gate 21 of the transistor M2 is connected to the readout signal wiring RWS via a contact 26. Also, the top gate 24 is connected to the cathode of the photodiode D1 via a contact 25. Note that operations of the photosensor according to this configuration are similar to the operations described above, and a description thereof has therefore been omitted.

### Embodiment 2

Below is a description of a display device according to Embodiment 2 of the present invention. Note that the same reference numerals have been used for constituent elements that have functions likewise to those of the constituent elements described in Embodiment 1, and detailed descriptions thereof have been omitted.

The display device according to Embodiment 2 has a configuration in which, in addition to the photosensor (photoreception element) that detects the brightness of external light as described in Embodiment 1, a photodiode (reference element) that is shielded from light to prevent external light from being incident thereon is provided in at least a portion of the pixels in the pixel region 1 of the active matrix substrate 100. Specifically, in this configuration, dark current is detected by the light-shielded photodiode (reference element), and the output of the photosensor (photoreception element) is corrected with use of the result of the detection. In other words, this configuration aims to compensate for the temperature dependency of the photodiode with a dark current value detected by the reference element.

A light-shielding layer of the reference element can be formed using either the same material as the electrodes of the pixel driving TFTs (M1r, M1g, and M1b shown in FIG. 2) in the pixel region 1 of the active matrix substrate 100, or the same material as the black matrix provided on the active matrix substrate 100 or on the common substrate, and also at the same time as and using the same process as these. Alternatively, the light-shielding layer can also be formed using the same material as various types of wiring on the active matrix substrate 100 (e.g., source wiring, or wiring provided in a layer above source wiring in the case of multilayer wiring). Also, in the case of configuring the display device as a semi-transmissive liquid crystal panel, the same material as a reflective layer may be used.

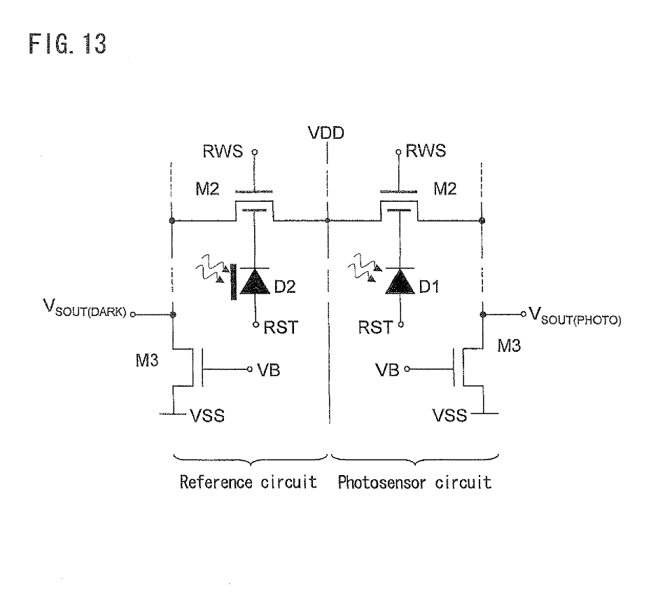

FIG. 13 is an equivalent circuit diagram showing a configuration of an example of the display device according to Embodiment 2, in which a photosensor circuit having the photodiode D1 (photoreception element) that receives external light, and a reference circuit having a photodiode D2 (reference element) that is shielded from light to prevent external light from being incident thereon are disposed adjacent to each other so as to be connected to a common VDD wiring line. Note that the density and proportion in which the photoreception elements and reference elements are disposed is arbitrary design matter. For example, one column of reference elements may be used to correct the output of one adjacent column of photoreception elements, or one column of reference elements may be used to correct the output of multiple columns of photoreception elements in the vicinity.

In the configuration in FIG. 13, the photodiode D2 is shielded from light in the reference circuit, and therefore only a dark current component is output as V_{SOUT(DARK)}, regardless of the brightness of external light. On the other hand, the photodiode D1 in the photosensor circuit receives external light, and outputs V_{SOUT(PHOTO)} in accordance with the brightness of the external light. Accordingly, correcting V_{SOUT(PHOTO)} with use of V_{SOUT(DARK)} enables obtaining photosensor output that is free from temperature dependency.

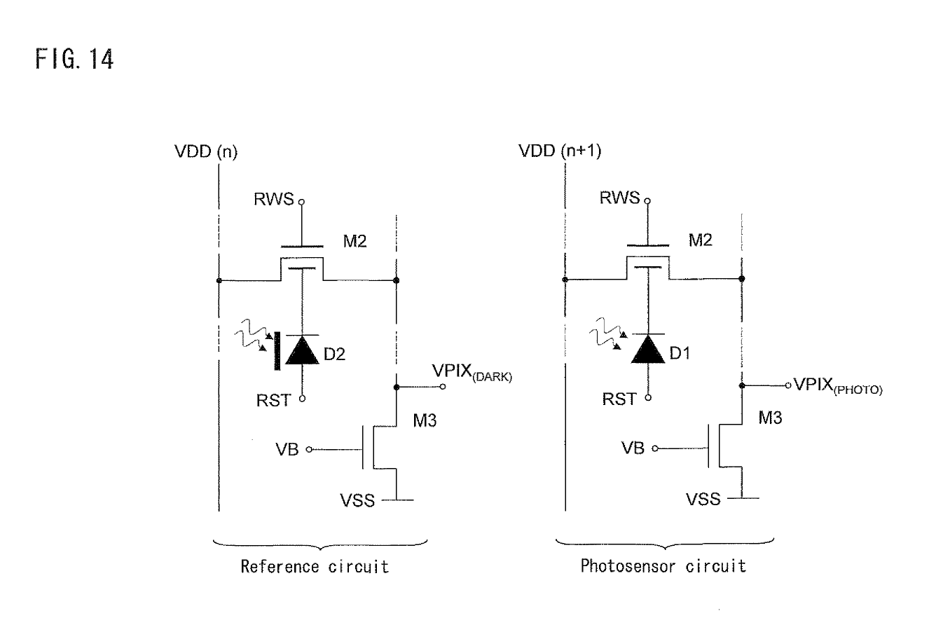

Note that although FIG. 13 shows an example of a configuration in which the photosensor circuit and the reference circuit are connected to a common VDD wiring line, a configuration is possible in which, as shown in FIG. 14, the photosensor circuit and the reference circuit are connected to separate adjacent VDD wiring lines. In this case as well, the operations are similar to the configuration in FIG. 13. Also, in the configurations shown in FIGS. 13 and 14, the VDD wiring may also serve as any of the source lines as shown in FIG. 2 in Embodiment 1, or may be wiring that is separate and independent from the source lines.

### Embodiment 3

Below is a description of a display device according to Embodiment 3 of the present invention. Note that the same reference numerals have been used for constituent elements that have functions likewise to those of the constituent elements described in Embodiments 1 and 2 above, and detailed descriptions thereof have been omitted.

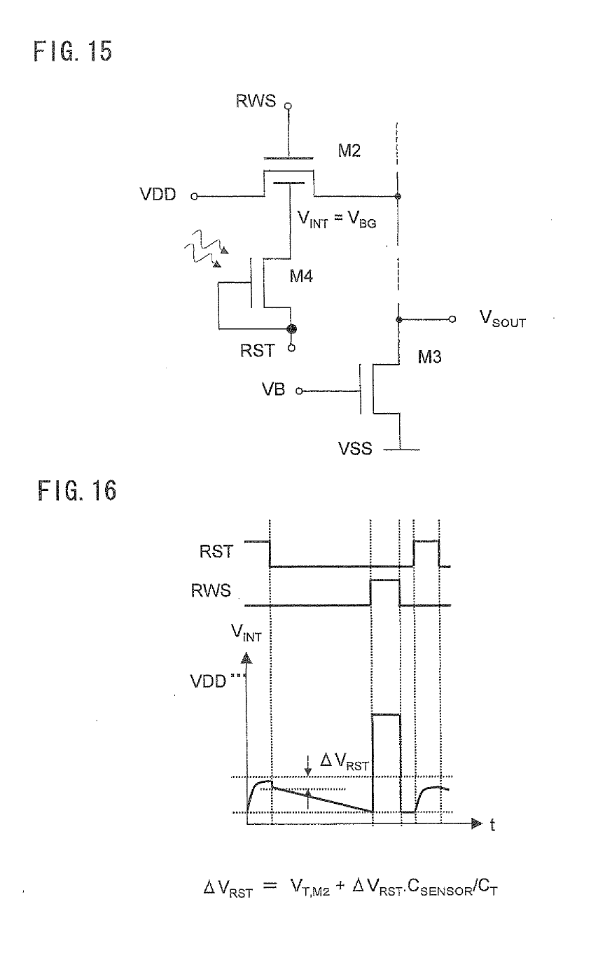

As shown in FIG. 15, the display device according to Embodiment 3 differs from Embodiment 1 in that a phototransistor (photo TFT) M4 is included in place of the photodiode D1 in the photosensor described in Embodiment 1.

The gate and the source of the phototransistor M4 are both connected to the reset wiring RST. The phototransistor M4 is not limited to being a polysilicon TFT having a high mobility, and can be an amorphous silicon TFT or a microcrystalline silicon TFT. Note that the transistor M2 can also be realized by an amorphous silicon TFT or a microcrystalline silicon TFT. Accordingly, the transistor M2 and the phototransistor M4 can be formed at the same time using the same material.

The following describes operations of the photosensor according to the present embodiment with reference to FIG. 16. FIG. 16 is a waveform diagram showing a relationship between input signals (RST and RWS) and V_{INT} in the photosensor according to Embodiment 3. Note that the reset signal RST and the readout signal RWS are the same as those shown in FIG. 5 in Embodiment 1. In the photosensor according to the present embodiment, when the reset signal RST is at high level, the potential V_{INT} of the gate electrode of the transistor M2 is expressed by Expression (6) below.

V_{INT}=V_{RSTH}−V_{T,M2} (6)

In Expression (6), V_{T,M2} is the threshold voltage of the transistor M2, and ΔV_{RST} is the pulse height of the reset signal (V_{RSTH}−V_{RSTL}), and since the voltage of the readout signal RWS is 0 V at this time, the transistor M2 is in the non-conducting state.

Next, the reset signal returns to the low level V_{RSTL}, and thus the photocurrent integration period begins. In the integration period, a photocurrent that is proportionate to the amount of incident light received by the phototransistor M4 flows out from the capacitance C_{BG} of the bottom gate, and the capacitance C_{BG} is discharged. Accordingly, the potential V_{INT} of the gate of the transistor M2 when the integration period ends is expressed by Expression (7) below.

V_{INT}=V_{RSTH}−V_{T,M2}−ΔV_{RST}·C_{SENSOR}/C_{T}−I_{PHOTO}·T_{INT}/C_{T} (7)

In Expression (7), I_{PHOTO} is the photocurrent of the phototransistor M4, and TNT is the length of the integration period. In the integration period as well, the voltage of the readout signal RWS is 0 V, and therefore the transistor M2 is in the non-conducting state. C_{SENSOR} is the capacitance of the phototransistor M4. C_{T} is the sum of the capacitance C_{BG} of the bottom gate, the capacitance C_{SENSOR} of the phototransistor M4, and a parasitic capacitance C_{TFT} of the transistor M2.

When the integration period ends, the readout signal RWS rises, and thus the readout period begins. Note that the readout period continues while the readout signal RWS is at high level. The readout principle in this case is similar to that described in Embodiment 1, and therefore a redundant description has been omitted.

As described above, the display device according to the present embodiment enables obtaining photosensor output even when the phototransistor M4 is used in place of a photodiode as the photodetection element of a photosensor. Also, in particular, forming the transistor M2 and the phototransistor M4 from an amorphous silicon TFT or a microcrystalline silicon TFT has the advantage of enabling more inexpensive manufacturing than when using polysilicon.

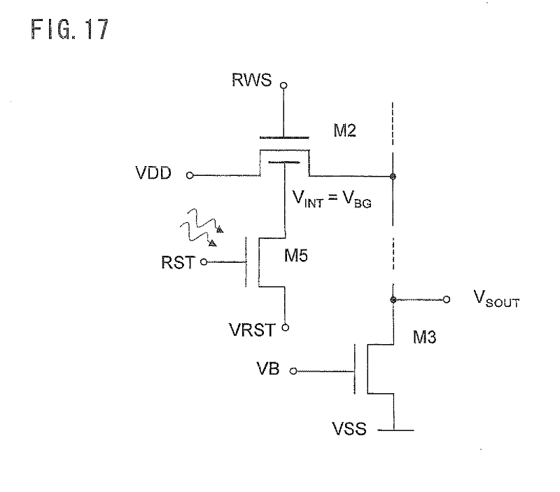

The following describes a variation of Embodiment 3 with reference to FIGS. 17 to 19. As shown in FIG. 17, the display device according to this variation includes a phototransistor M5 in place of the phototransistor M4 shown in FIG. 15. The phototransistor M5 is the same as the phototransistor M4 in that the gate is connected to the reset wiring RST, but differs from the phototransistor M4 in that the source is connected to wiring for supplying a second reset signal VRST that is different from the reset signal RST.

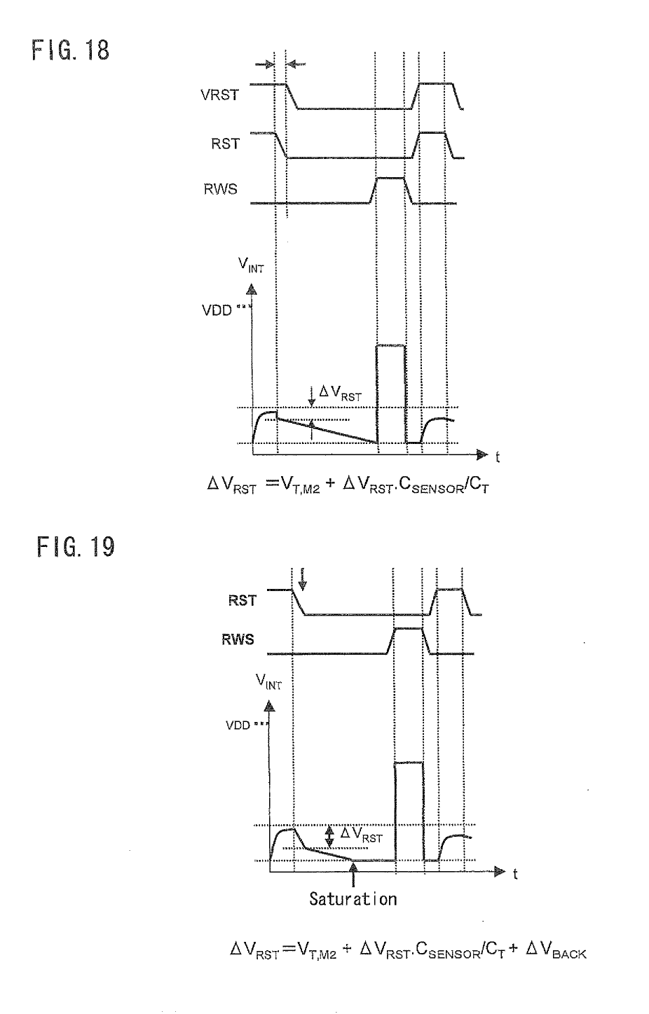

The following describes operations of the photosensor according to this variation with reference to FIGS. 18 and 19. FIG. 18 is a waveform diagram showing a relationship between V_{INT} and various signals that are applied to the photosensor according to this variation. FIG. 19 is a waveform diagram showing, as a comparative example, change in V_{INT} in the case where the drop in the potential of the reset signal RST was not steep in the configuration shown in FIG. 15.

As shown in FIG. 19, in the case where the drop in the potential of the reset signal RST was not steep in the configuration shown in FIG. 15, the potential V_{INT} of the gate electrode of the transistor M2 drops a substantial amount (ΔV_{BACK} shown in FIG. 19) in the potential drop period of the reset signal RST. This reason for this is that the phototransistor M4 has bidirectional conductivity, unlike a photodiode. In this case, the dynamic range of the pixel is reduced by an amount commensurate to the drop ΔV_{BACK}, thus causing the problem of saturation by a small amount of light.

In the configuration according to the present embodiment, in order to address this problem, separate reset signals RST and VRST are respectively applied to the gate and source of the phototransistor M5 as described above. As shown in FIG. 18, the drop in the potential of the second reset signal VRST applied to the source of the phototransistor M5 begins once the reset signal RST is completely at low level, that is to say, once the phototransistor M5 has switched to the off state. Accordingly, as shown by a comparison of FIGS. 18 and 19, the drop in the potential V_{INT} (ΔV_{BACK}) seen in FIG. 19 does not occur in the configuration of the above-described variation, thus enabling realizing a photosensor having a wide dynamic range.

Note that the above description gives an example of the configuration in which the photodiode of Embodiment 1 has been replaced with a phototransistor. However, a configuration in which the photodiode of Embodiment 2 has been replaced with a phototransistor is also possible, and is an embodiment of the present invention.

### Embodiment 4

Below is a description of a display device according to Embodiment 4 of the present invention. Note that the same reference numerals have been used for constituent elements that have functions likewise to those of the constituent elements described in Embodiments 1 to 3, and detailed descriptions thereof have been omitted.

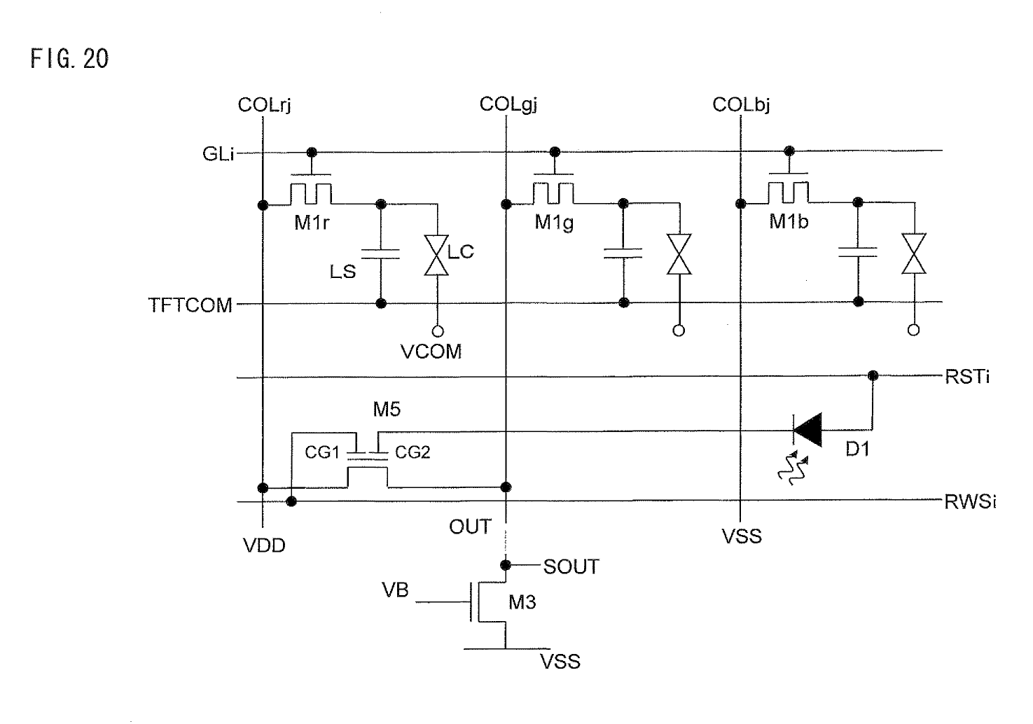

As shown in FIG. 20, the display device according to the present embodiment has a configuration in which the double gate TFT included in the display device according to Embodiment 1 has been replaced with a floating gate TFT (M6).

The floating gate TFT MG includes two control gates CG1 and CG2. The control gate CG1 is connected to the readout signal wiring RWS. The control gate CG2 is connected to the cathode of the photodiode D1. The control gate CG2 can be used to control the threshold voltage of the control gate CG1.

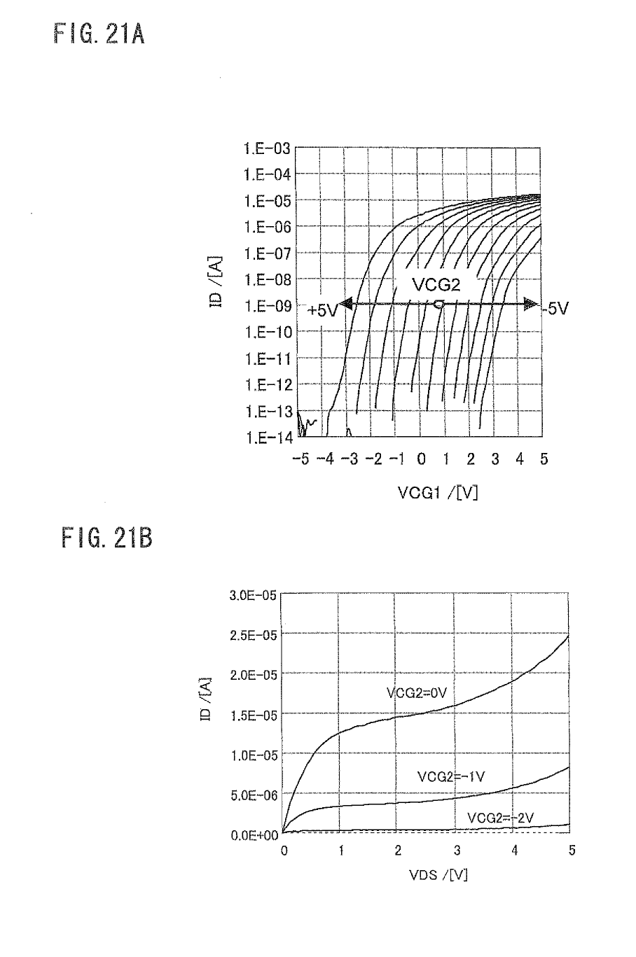

FIG. 21A is a characteristics diagram showing a relationship between potential V_{CG1} (units of V) of the control gate CG1, drain current ID (units of A), and potential V_{CG2} (units of V) of the control gate CG2 in the floating gate TFT M6. Also, FIG. 21B is a characteristics diagram showing a relationship between drain-source potential difference V_{DS} (units of V), drain current ID (units of A), and potential V_{CG2} (units of V) of the control gate CG2 in the floating gate Tyr MG. Note that although FIG. 21A shows characteristics in the case where the potential difference between the drain and source is 0.1 V and FIG. 21B shows characteristics in the case where the potential V_{CG1} of the control gate CG1 is 5 V, these are merely examples, and the floating gate TFT characteristics that are applicable to the present invention are not intended to be limited to these examples.

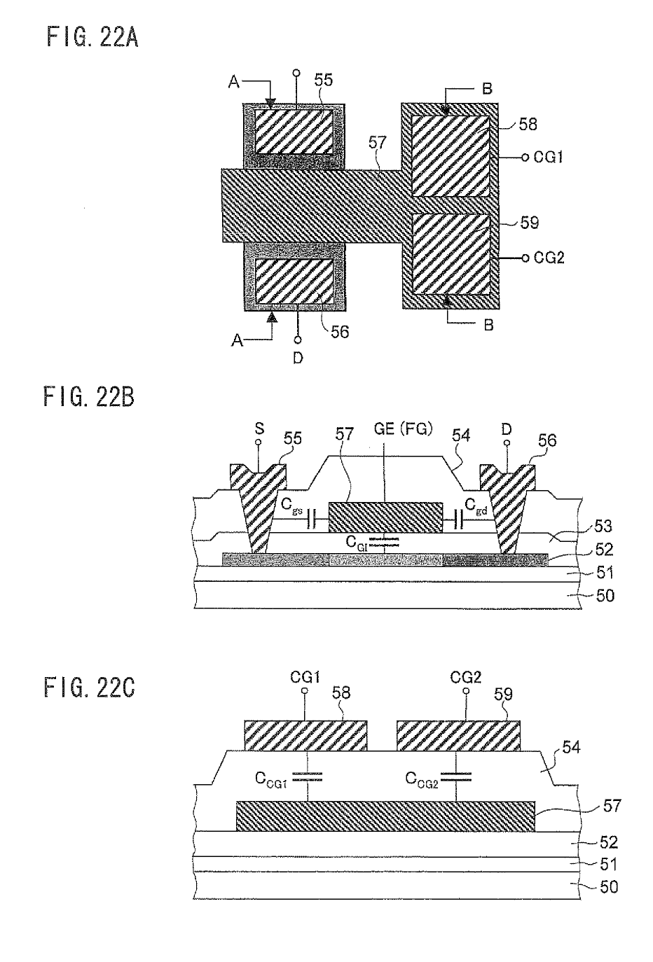

FIG. 22A is a plan view showing a configuration of the floating gate TFT MG. FIG. 22B is a cross-sectional diagram showing a cross section taken along arrows A-A in FIG. 22A. FIG. 22C is a cross-sectional diagram showing a cross section taken along arrows B-B in FIG. 22A. As shown in FIGS. 22A to 22C, the floating gate TFT MG has a configuration in which a base coat 51, a semiconductor layer 52, a gate insulating film 53, a floating gate 57, and an interlayer insulating film 54 are successively formed on a glass substrate 50 of the active matrix substrate 100. The control gates CG1 and CG2 are formed on the interlayer insulating film 54. The semiconductor layer 52 is connected to a source electrode 55 and a drain electrode 56.

A voltage V_{FG} on the floating gate 57 is expressed by Expression (8) below.

V_{FG}=C_{CG1}/C_{T}×V_{CG1}+C_{CG2}/C_{T}×V_{CG2}+C_{gs}/C_{T}×V_{S}+C_{gd}/C_{T}×V_{D} (8)

Note that C_{T}=C_{CG1}+C_{CG2}+C_{gd}+C_{gs}.

Also, if C_{gd} and C_{gs} are very small compared to C_{CG1} and C_{CG2}, according to Expression (8) above, the voltage V_{FG} on the floating gate 57 can be expressed as shown in Expression (9) below.

V_{FG}=C_{CG1}/C_{T}×V_{CG1}+C_{CG2}/C_{T}×V_{CG2} (9)

Note that the magnitude of C_{CG1} and C_{CG2} can be appropriately adjusted by adjusting the surface area of the control gates CG1 and CG2.

Note that operations of the photosensor according to the present embodiment are similar to those of the photosensor described in Embodiment 1, and therefore a redundant description has been omitted.

Note that the following are advantages of using a floating gate TFT in the display device according to the present embodiment. Firstly, since the capacitance C_{CG2} formed between the control gate CG2 and the floating gate functions as a capacitance that accumulates photocurrent from the photodiode D1, there is no need to separately provide the capacitor C_{INT} as with the conventional photosensor shown in FIG. 23. Compared to the above-described conventional photosensor, the photosensor of the present embodiment can have fewer constituent parts since a capacitor is unnecessary, thus enabling improving the pixel aperture ratio.

Although the present invention has been described based on Embodiments 1 to 4, the present invention is not limited to only the above-described embodiments, and it is possible to make various changes within the scope of the invention.

For example, the above embodiments describe an example of a configuration in which the wiring VDD and OUT that the photosensor is connected to are also used as the source wiring COL. This configuration has the advantage that the pixel aperture ratio is high. However, a configuration is possible in which the photosensor wiring VDD and OUT is provided separately from the source wiring COL.

### INDUSTRIAL APPLICABILITY

The present invention is industrially applicable as a display device having a photosensor.

1. A display device comprising a photosensor on an active matrix substrate,
the photosensor comprising:
a photodetection element that receives incident light;
reset signal wiring that supplies a reset signal to the photosensor;
readout signal wiring that supplies a readout signal to the photosensor; and
a sensor switching element that, in accordance with the readout signal, reads out photocurrent that has been output from the photodetection element from when the reset signal is supplied until when the readout signal is supplied,
wherein the sensor switching element is a four-terminal amplifier having two control electrodes.

2. The display device according to claim 1, wherein the four-terminal amplifier is a double gate TFT having a top gate and a bottom gate as the control electrodes.

3. The display device according to claim 2, wherein the top gate is connected to output of the photodetection element, and the bottom gate is connected to the readout signal wiring.

4. The display device according to claim 2, wherein the top gate is connected to the readout signal wiring, and the bottom gate is connected to output of the photodetection element.

5. The display device according to claim 2, further comprising:
a backlight,
wherein the photosensor further comprises a light-shielding layer between the photodetection element and the backlight, and
the light-shielding layer and the bottom gate are formed from the same metal material.

6. The display device according to claim 5, wherein the light-shielding layer and the bottom gate have the same thickness.

7. The display device according to claim 1, wherein the four-terminal amplifier is a floating gate TFT having two floating gates as the control electrodes.

8. The display device according to claim 1,
wherein the photodetection element includes a photoreception element that receives light, and a reference element that is shielded from light by the light-shielding layer and detects dark current, and
the display device further comprises a correction circuit that corrects output of the photoreception element with use of output from the reference element.

9. The display device according to claim 8, wherein the photoreception element and the reference element are provided in a pixel region of the active matrix substrate.

10. The display device according to claim 8, wherein the light-shielding layer is formed from the same material as any metal layer formed on the active matrix substrate.

11. The display device according to claim 8, wherein the light-shielding layer is formed from the same material as a black matrix formed on the active matrix substrate or on a common substrate.

12. The display device according to claim 1, wherein the photodetection element is a photodiode.

13. The display device according to claim 12,
wherein one of the control electrodes is connected to the readout signal wiring, and
the other of the control electrodes is connected to a cathode of the photodiode.

14. The display device according to claim 12,
wherein one of two terminals other than the control electrodes in the four-terminal amplifier is connected to constant potential wiring, and
the other of the two terminals other than the control electrodes in the four-terminal amplifier is connected to sensor signal output wiring from the photosensor.

15. The display device according to claim 12, wherein an anode of the photodiode is connected to the reset signal wiring.

16. The display device according to claim 1, wherein the photodetection element is a phototransistor.

17. The display device according to claim 1, wherein the photodetection element is provided in a pixel region of the active matrix substrate.

18. The display device according to claim 1, further comprising:
a common substrate opposing the active matrix substrate; and
liquid crystal sandwiched between the active matrix substrate and the common substrate.
